(19) United States
(12) Patent Application Publication
(10) Pub. No.: US 2026/0096479 A1
(43) Pub. Date: Apr. 2, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chung-Yu KE, Taichung City (TW); Bo-Hung HUANG, Taichung City (TW); Kun-Sheng TSAI, Taichung City (TW); Liang-Pin CHEN, Taichung City (TW)

(73) Assignee: SILICONWARE PRECISION INDUSTRIES CO., LTD., Taichung City (TW)

(21) Appl. No.: 18/949,213

(22) Filed: Nov. 15, 2024

(30) Foreign Application Priority Data
Sep. 30, 2024 (TW) 113137378

(51) Int. Cl. H01L 25/16; G02B 6/42; H01L 21/56; H01L 21/683; H01L 23/00; H01L 23/31; H01L 23/498; H01L 23/538; H05K 1/18

(52) U.S. Cl. CPC H10W 90/00; G02B 6/4201; H10P 72/74; H10W 70/611; H10W 90/401; H05K 1/181; H10W 74/131; H10W 74/15; H10W 90/724; H10W 90/734

(57) ABSTRACT

An electronic package and a manufacturing method thereof are provided, in which a bridge chip is disposed on one side of a wiring structure, and an electronic component and an optical engine are disposed on the other side of the wiring structure. The bridge chip, the electronic component and the optical engine are electrically connected to the wiring structure, so that the electronic component and the optical engine can be electrically connected to each other via the bridge chip, such that the path of electrical transmission is shortened and the loss and power consumption of data transmission are reduced.

### BACKGROUND

### 1. Technical Field

The present disclosure relates to a semiconductor device, and more particularly, to an electronic package with an optical engine and a manufacturing method thereof.

### 2. Description of Related Art

With the vigorous development of the electronics industry, electronic products are gradually moving towards multi-function and high performance. The current application of fifth-generation (5G) communication technology has expanded to Internet of Things (IoT), Industrial Internet of Things (IIoT), cloud, artificial intelligence (AI), autonomous car, and medical, etc., and with the expansion of the application level, a large amount of data is generated and needs to be efficiently transmitted, calculated and stored, especially the demand for data transmission has emerged in large quantities, causing the industry to begin to use “light” instead of “electricity” as the carrier of data transmission, thereby improving capacity, efficiency, or distance of transmission, and reducing energy consumption during the transmission process.

Please refer to FIG. 1. FIG. 1 is a schematic cross-sectional view of a conventional semiconductor package 1 used for optical communication. The semiconductor package 1 includes a circuit board 10, and a substrate 11, a semiconductor chip 12 and an optical transceiver module 13 disposed on the circuit board 10, wherein the semiconductor chip 12 is disposed on the substrate 11, and the optical transceiver module 13 is disposed on the circuit board 10 and connected to an optical fiber 14.

However, in the aforementioned optical communication semiconductor package 1, the electrical signals of the semiconductor chip 12 need to pass through the substrate 11 and the circuit board 10 in order to be transmitted to the optical transceiver module 13, so that the electrical signal transmission path is excessively long, resulting in issues such as loss of data transmission and increasing power consumption.

Please refer to FIG. 2. In order to solve the aforementioned problems, the industry has developed another semiconductor package 2 for optical communication, in which a semiconductor chip 22 and an optical device 23 for connecting an optical fiber 24 are disposed on a substrate 21, and then the substrate 21 is disposed on a circuit board 20, so that the optical device 23 can transmit electrical signals via the substrate 21 and the semiconductor chip 22, and the electrical signal transmission path is simplified.

However, regardless of the aforementioned semiconductor package in FIG. 1 and FIG. 2, the electrical signal transmission paths are still too long and cannot cope with rapid and substantial growth in data transmission requirements of future technologies and products.

Therefore, how to overcome the aforementioned problems of the prior art has become an urgent issue to be solved.

### SUMMARY

In view of the aforementioned shortcomings of the prior art, the present disclosure provides an electronic package, which comprises: a bridge chip; a wiring structure disposed on the bridge chip; an electronic component disposed on the wiring structure; and an optical engine disposed on the wiring structure, wherein the electronic component and the optical engine are electrically connected to each other via the bridge chip, wherein the optical engine includes a packaging structure, a semiconductor component disposed in the packaging structure, and an optical chip module disposed on the packaging structure.

The present disclosure further provides a method of manufacturing an electronic package, the method comprises: providing a bridge chip on which a wiring structure is formed; and disposing an electronic component and an optical engine on the wiring structure, wherein the electronic component and the optical engine are electrically connected to each other via the bridge chip, wherein the optical engine includes a packaging structure, a semiconductor component disposed in the packaging structure, and an optical chip module disposed on the packaging structure.

In the aforementioned electronic package and method, the present disclosure further comprises disposing the bridge chip on a first carrier, and forming an encapsulation layer on the first carrier to cover the bridge chip.

In the aforementioned electronic package and method, the present disclosure further comprises forming a plurality of conductive pillars on the first carrier, wherein the plurality of conductive pillars are covered by the encapsulation layer.

In the aforementioned electronic package and method, the present disclosure further comprises forming the wiring structure on the encapsulation layer, wherein the wiring structure is electrically connected to the bridge chip.

In the aforementioned electronic package and method, the present disclosure further comprises disposing one side of the wiring structure on a second carrier, and removing the first carrier to expose the encapsulation layer, and then forming a circuit structure on the encapsulation layer.

In the aforementioned electronic package and method, the present disclosure further comprises disposing one side of the circuit structure on a third carrier, and removing the second carrier to expose the wiring structure.

In the aforementioned electronic package and method, the present disclosure further comprises disposing the electronic component and the optical engine on the wiring structure, wherein the electronic component and the optical engine are electrically connected to the wiring structure.

In the aforementioned electronic package and method, the present disclosure further comprises forming a packaging layer on the wiring structure to cover the electronic component and the optical engine, wherein a part of the optical engine is exposed from the packaging layer.

In the aforementioned electronic package and method, the present disclosure further comprises removing the third carrier, and disposing the bridge chip on a substrate.

In the aforementioned electronic package and method, the present disclosure further comprises disposing the substrate on a circuit board.

In the aforementioned electronic package and method, wherein the optical engine is connected to an optical fiber. As can be seen from the above, in the electronic package and manufacturing method thereof of the present disclosure, a bridge chip is disposed on one side of a wiring structure, and an electronic component and an optical engine are disposed on the other side of the wiring structure, and the bridge chip, the electronic component and the optical engine are electrically connected to the wiring structure, so that the electronic component and the optical engine can be electrically connected to each other via the bridge chip, such that the path of electrical transmission is shortened and the loss and power consumption of data transmission are reduced.

### BRIEF DESCRIPTION OF THE DRAWINGS

FIG. 1 is a schematic cross-sectional view showing a conventional semiconductor package for optical communication.

FIG. 2 is a schematic cross-sectional view showing another conventional semiconductor package for optical communication.

FIG. 3A to FIG. 3G are schematic cross-sectional views showing an electronic package and a manufacturing method thereof of the present disclosure.

FIG. 4 is a schematic cross-sectional view showing an optical engine of an electronic package of the present disclosure.

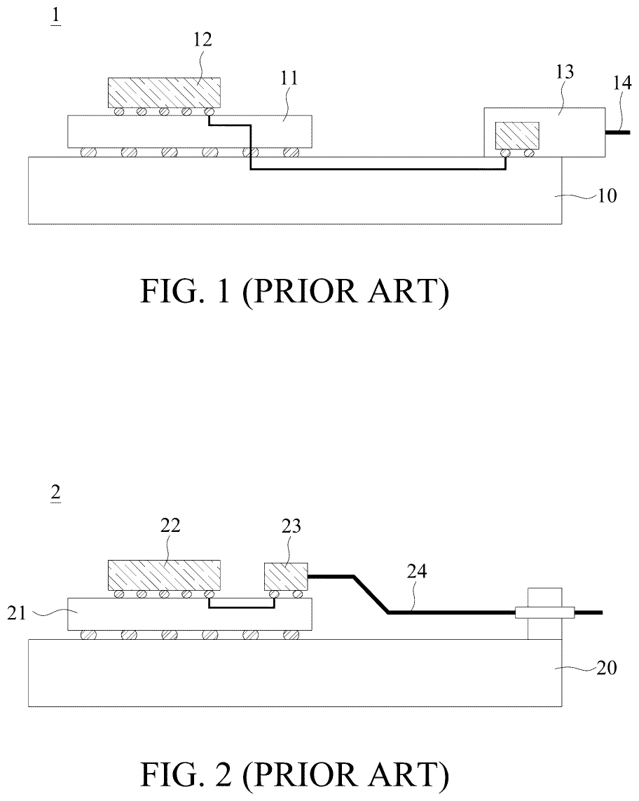

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “third,” “one,” “a” and the like are merely for clear explanation rather than limiting the practicable scope of the present disclosure, and thus, alterations or adjustments of the relative relationships thereof without essentially altering the technical contents should still be considered in the practicable scope of the present disclosure.

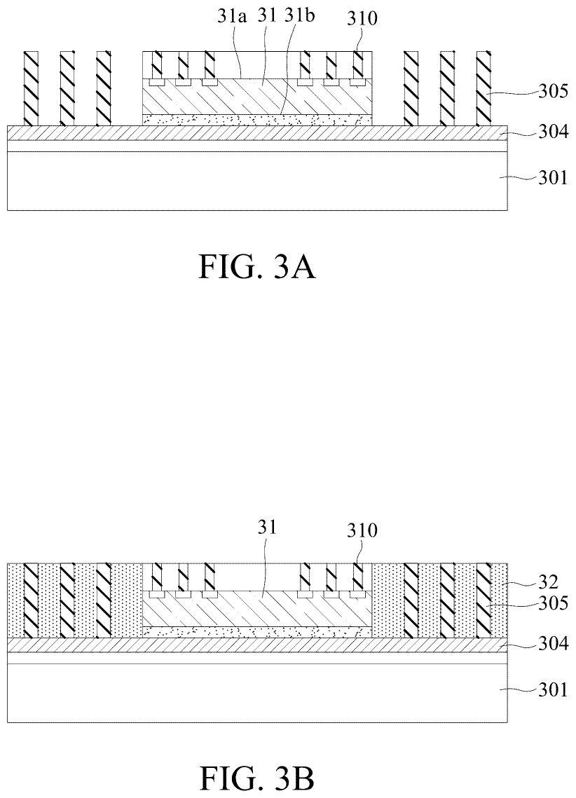

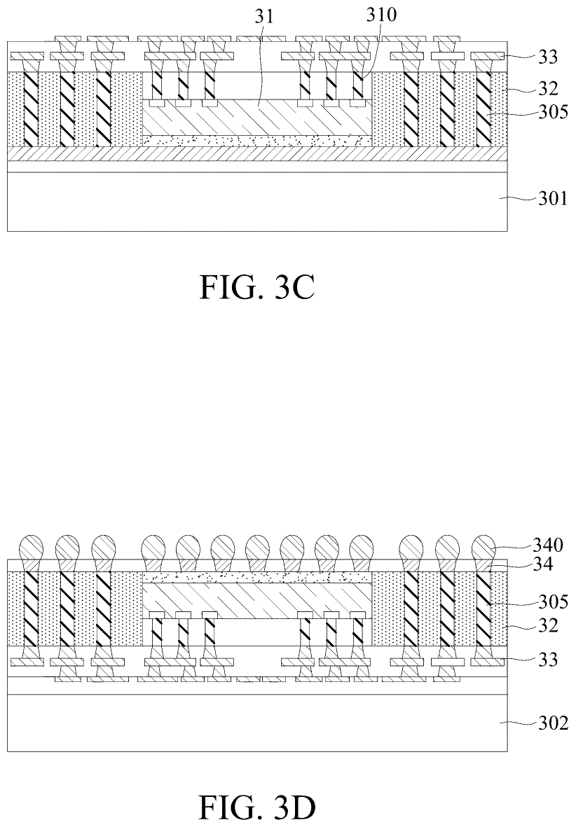

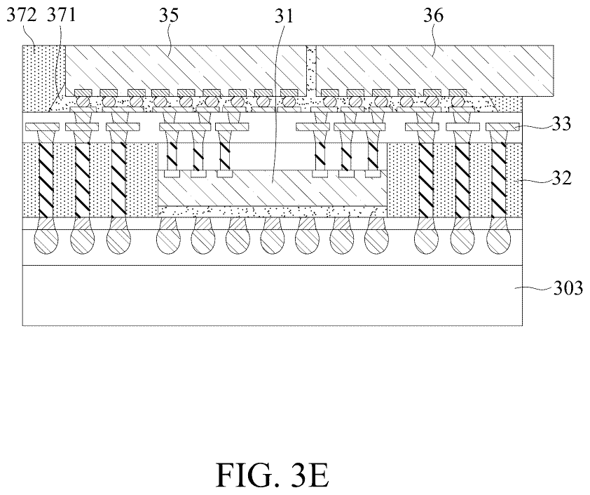

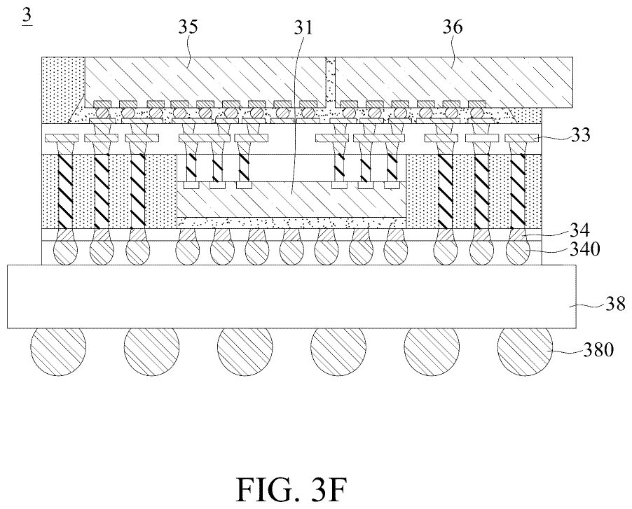

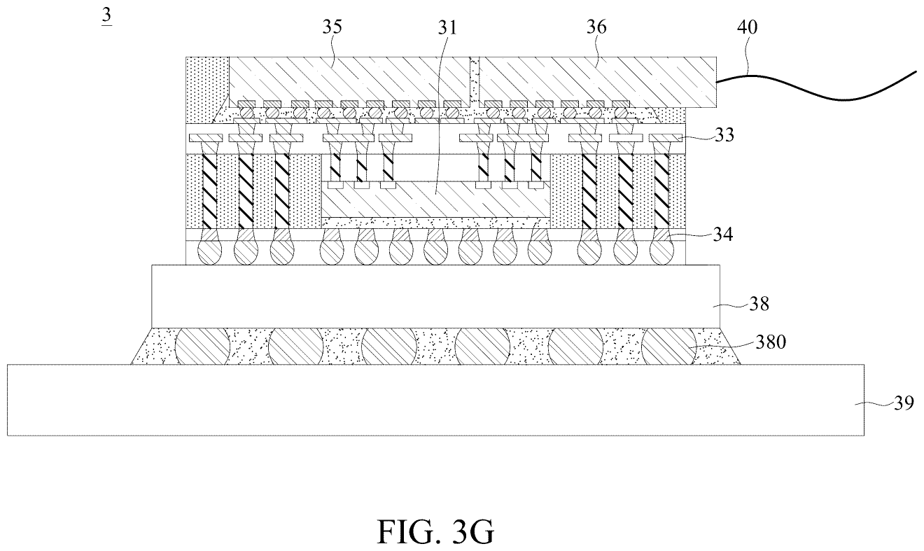

FIG. 3A to FIG. 3G are schematic cross-sectional views showing an electronic package 3 and a manufacturing method thereof of the present disclosure.

As shown in FIG. 3A, a conductive metal layer 304 is formed on a first carrier 301, a plurality of conductive pillars 305 are formed on the conductive metal layer 304, and at least one bridge chip 31 is disposed on the conductive metal layer 304.

The bridge chip 31 has an active surface 31a and an inactive surface 31b opposite to the active surface 31a, wherein the inactive surface 31b of the bridge chip 31 is disposed on the first carrier 301 via an adhesive layer, and a plurality of conductive bumps 310 are formed on the active surface 31a.

In one embodiment, the first carrier 301 is made of, for example, glass; the conductive metal layer 304 is, for example, a titanium (Ti)/copper (Cu) metal layer; the conductive pillars 305 can be made of copper or other metals; and the bridge chip 31 is, for example, a fan-out embedded bridge (FOEB) chip.

Moreover, a release layer can be formed between the first carrier 301 and the conductive metal layer 304 to facilitate subsequent removal of the first carrier 301.

As shown in FIG. 3B, an encapsulation layer 32 is formed on the first carrier 301 and covers the plurality of conductive pillars 305 and the bridge chip 31.

Furthermore, the encapsulation layer 32 can be thinned such that one end of each of the plurality of conductive pillars 305 and one end of each of the plurality of conductive bumps 310 are exposed from the encapsulation layer 32.

In one embodiment, the material forming the encapsulation layer 32 is an insulating material, such as polyimide (PI), epoxy molding colloid, or epoxy molding compound. The encapsulation layer 32 can be formed by molding, lamination, or coating.

As shown in FIG. 3C, a wiring structure 33 is formed on the encapsulation layer 32, and the wiring structure 33 is electrically connected to the bridge chip 31 (the plurality of conductive bumps 310) and the plurality of conductive pillars 305. The wiring structure 33 is, for example, a redistribution layer (RDL) structure.

As shown in FIG. 3D, one side of the wiring structure 33 is disposed on a second carrier 302, and the first carrier 301 and the conductive metal layer 304 are removed to expose the encapsulation layer 32 and the other end of each of the plurality of conductive pillars 305, and then a circuit structure 34 is formed on the encapsulation layer 32, and the circuit structure 34 is electrically connected to the plurality of conductive pillars 305.

Then, a plurality of conductive components 340 are disposed on the circuit structure 34, wherein the plurality of conductive components 340 are, for example, solder balls.

As shown in FIG. 3E, one side of the circuit structure 34 and the plurality of conductive components 340 are disposed on a third carrier 303, and the second carrier 302 is removed to expose the wiring structure 33.

Then, an electronic component 35 and an optical engine 36 are disposed on the wiring structure 33, and the electronic component 35 and the optical engine 36 are electrically connected to the wiring structure 33, such that the electronic component 35 and the optical engine 36 can be electrically connected to each other via the bridge chip 31, wherein the optical engine 36 protrudes from a side of the encapsulation layer 32 and a side of the wiring structure 33 for subsequent optical fiber connection.

The electronic component 35 is an active element such as a switch chip, a system on a chip (SOC), a high bandwidth memory (HBM) chip, or a chip with other functions. Alternatively, the electronic component 35 can also be a passive element such as a resistor, a capacitor, or an inductor. The electronic component 35 can be electrically connected to the wiring structure 33 via a plurality of conductive bumps such as solder bumps, copper bumps, or others in a flip-chip manner.

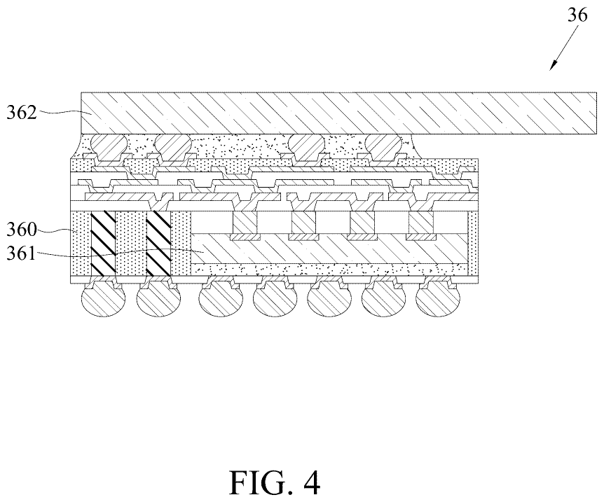

Please also refer to FIG. 4. The optical engine 36 includes a packaging structure 360, a semiconductor component 361 disposed in the packaging structure 360, and an optical chip module 362 disposed on the packaging structure 360. The packaging structure 360 is, for example, a fan-out package on package (FO-PoP) structure. The semiconductor component 361 is, for example, an electronic integrated circuit (EIC). The optical chip module 362 (photonic IC [PIC] module), for example, includes a coupling device, an optical chip, a total reflection mirror, a fiber array unit (FAU), etc. The optical engine 36 can be electrically connected to the wiring structure 33 via a plurality of conductive bumps such as solder bumps, copper bumps, or others.

In addition, an underfill 371 can be formed between the electronic component 35 and the optical engine 36 and between the wiring structure 33 and the electronic component 35 and the optical engine 36. A packaging layer 372 is formed on the wiring structure 33 and covers the electronic component 35 and the optical engine 36, and the optical engine 36 is exposed from the packaging layer 372 for subsequent optical fiber connection.

As shown in FIG. 3F, the third carrier 303 is removed to obtain the electronic package 3 of the present disclosure. In addition, the electronic package 3 can be disposed on one side of a substrate 38 via the plurality of conductive components 340, and a plurality of solder balls 380 are placed on the other side of the substrate 38.

As shown in FIG. 3G, the electronic package 3 can be further connected onto an external device such as a circuit board 39 via the substrate 38 and the plurality of solder balls 380, and the optical engine 36 is connected to an optical fiber 40.

Through the aforementioned manufacturing process, the present disclosure further provides an electronic package 3, which includes: a bridge chip 31; a wiring structure 33 disposed on the bridge chip 31; an electronic component 35 disposed on the wiring structure 33; and an optical engine 36 disposed on the wiring structure 33, wherein the electronic component 35 and the optical engine 36 are electrically connected to each other via the bridge chip 31, wherein the optical engine 36 includes a packaging structure 360, a semiconductor component 361 disposed in the packaging structure 360, and an optical chip module 362 disposed on the packaging structure 360.

The electronic package 3 further includes a circuit structure 34 to arrange the bridge chip 31 thereon; a plurality of conductive pillars 305 disposed on the circuit structure 34; and an encapsulation layer 32 formed on the circuit structure 34 and covering the bridge chip 31 and the plurality of conductive pillars 305, wherein the wiring structure 33 is formed on the encapsulation layer 32.

The electronic package 3 further includes a substrate 38 for the bridge chip 31 (the circuit structure 34) to dispose thereon, wherein the circuit structure 34 can be electrically connected to the substrate 38 via a plurality of conductive components 340.

The electronic package 3 further includes a circuit board 39 for the substrate 38 to be connected, wherein the substrate 38 can be electrically connected to the circuit board 39 via a plurality of solder balls 380, and the optical engine 36 can be connected to an optical fiber 40.

To sum up, in the electronic package and manufacturing method thereof of the present disclosure, a bridge chip is disposed on one side of a wiring structure, and an electronic component and an optical engine are disposed on the other side of the wiring structure, and the bridge chip, the electronic component and the optical engine are electrically connected to the wiring structure, so that the electronic component and the optical engine can be electrically connected to each other via the bridge chip, such that the path of electrical transmission is shortened and the loss and power consumption of data transmission are reduced.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a bridge chip;
a wiring structure disposed on the bridge chip;
an electronic component disposed on the wiring structure; and
an optical engine disposed on the wiring structure, wherein the electronic component and the optical engine are electrically connected to each other via the bridge chip, wherein the optical engine includes a packaging structure, a semiconductor component disposed in the packaging structure, and an optical chip module disposed on the packaging structure.

2. The electronic package of claim 1, further comprising a circuit structure on which the bridge chip is disposed.

3. The electronic package of claim 2, further comprising a plurality of conductive pillars disposed on the circuit structure.

4. The electronic package of claim 2, further comprising an encapsulation layer formed on the circuit structure and covering the bridge chip.

5. The electronic package of claim 4, wherein the wiring structure is formed on the encapsulation layer and electrically connected to the bridge chip.

6. The electronic package of claim 1, further comprising a substrate on which the bridge chip is disposed.

7. The electronic package of claim 6, further comprising a circuit board on which the substrate is disposed.

8. The electronic package of claim 1, further comprising a packaging layer formed on the wiring structure and covering the electronic component and the optical engine, wherein a part of the optical engine is exposed from the packaging layer.

9. The electronic package of claim 1, wherein the optical engine is connected to an optical fiber.

10. A method of manufacturing an electronic package, comprising:
providing a bridge chip on which a wiring structure is formed; and
disposing an electronic component and an optical engine on the wiring structure, wherein the electronic component and the optical engine are electrically connected to each other via the bridge chip, wherein the optical engine includes a packaging structure, a semiconductor component disposed in the packaging structure, and an optical chip module disposed on the packaging structure.

11. The method of claim 10, further comprising disposing the bridge chip on a first carrier, and forming an encapsulation layer on the first carrier to cover the bridge chip.

12. The method of claim 11, further comprising forming a plurality of conductive pillars on the first carrier, wherein the plurality of conductive pillars are covered by the encapsulation layer.

13. The method of claim 11, further comprising forming the wiring structure on the encapsulation layer, wherein the wiring structure is electrically connected to the bridge chip.

14. The method of claim 13, further comprising disposing one side of the wiring structure on a second carrier, and removing the first carrier to expose the encapsulation layer, and then forming a circuit structure on the encapsulation layer.

15. The method of claim 14, further comprising disposing one side of the circuit structure on a third carrier, and removing the second carrier to expose the wiring structure.

16. The method of claim 15, further comprising disposing the electronic component and the optical engine on the wiring structure, wherein the electronic component and the optical engine are electrically connected to the wiring structure.

17. The method of claim 16, further comprising forming a packaging layer on the wiring structure to cover the electronic component and the optical engine, wherein a part of the optical engine is exposed from the packaging layer.

18. The method of claim 16, further comprising removing the third carrier, and disposing the bridge chip on a substrate.

19. The method of claim 18, further comprising disposing the substrate on a circuit board.

20. The method of claim 10, wherein the optical engine is connected to an optical fiber.
